(19) United States
(12) Patent Application Publication
(10) Pub. No.: US 2024/0203867 A1
(43) Pub. Date: Jun. 20, 2024

(54) SKIP VIA WITH DISCONTINUOUS DIELECTRIC CAP

(71) Applicant: International Business Machines Corporation, Armonk, NY (US)

(72) Inventors: Nicholas Anthony Lanzillo, Wynantskill, NY (US); Koichi Motoyama, Clifton Park, NY (US); Lawrence A. Clevenger, Saratoga Springs, NY (US); Ruilong Xie, Niskayuna, NY (US)

(21) Appl. No.: 18/065,747

(22) Filed: Dec. 14, 2022

(51) Int. Cl. H01L 23/522; H01L 21/768

(52) U.S. Cl. CPC H01L 23/5226; H01L 21/76877

(57) ABSTRACT

One or more systems, devices, and/or methods of fabrication provided herein relate to semiconductor devices with discontinuous dielectric caps. According to one embodiment, a semiconductor device can comprise a first level of interconnect wiring, a second level of interconnect wiring, a third level of interconnect wiring, a discontinuous dielectric cap over the second level of interconnect wiring and a skip via connecting the first level of interconnect wiring to the third level of interconnect wiring.

### BACKGROUND

The subject disclosure relates to skip vias, and more specifically, to self-aligned skip vias with discontinuous dielectric caps.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later.

### DESCRIPTION OF THE DRAWINGS

FIGS. 1A and 1B illustrate semiconductor devices with continuous dielectric caps in accordance with one or more embodiments described herein.

FIGS. 2A and 2B illustrate semiconductor devices with discontinuous dielectric caps in accordance with one or more embodiments described herein.

FIG. 3A illustrates a semiconductor device with a continuous dielectric cap in accordance with one or more embodiments described herein.

FIGS. 3B and 3C illustrate semiconductor devices with discontinuous dielectric caps in accordance with one or more embodiments described herein.

FIG. 4A illustrates a first portion of a productions process for fabrication of a semiconductor device in accordance with one or more embodiments described herein.

FIG. 4B illustrates a second portion of a production process for fabrication of a semiconductor device in accordance with one or more embodiments described herein.

FIG. 5 illustrates an alternative second portion of a production process for fabrication of a semiconductor device in accordance with one or more embodiments described herein.

FIG. 6 illustrates an alternative second portion of a production process for fabrication of a semiconductor device in accordance with one or more embodiments described herein.

FIG. 7A illustrates a first stage of production of a semiconductor device in accordance with one or more embodiments described herein.

FIG. 7B illustrates a second stage of production of a semiconductor device in accordance with one or more embodiments described herein.

FIG. 8A illustrates a third stage of production of a semiconductor device in accordance with one or more embodiments described herein.

FIG. 8B illustrates a fourth stage of production of a semiconductor device in accordance with one or more embodiments described herein.

FIG. 9A illustrates a fifth stage of production of a semiconductor device in accordance with one or more embodiments described herein.

FIG. 10A illustrates a seventh stage of production of a semiconductor device in accordance with one or more embodiments described herein.

FIG. 10B illustrates an eighth stage of production of a semiconductor device in accordance with one or more embodiments described herein.

FIG. 11A illustrates an alternative first stage of production of a semiconductor device in accordance with one or more embodiments described herein.

FIG. 11B illustrates an alternative second stage of production of a semiconductor device in accordance with one or more embodiments described herein.

FIG. 12A illustrates an alternative third stage of production of a semiconductor device in accordance with one or more embodiments described herein.

FIG. 12B illustrates an alternative fourth stage of production of a semiconductor device in accordance with one or more embodiments described herein.

FIG. 13A illustrates an alternative fifth stage of production of a semiconductor device in accordance with one or more embodiments described herein.

FIG. 13B illustrates an alternative sixth stage of production of a semiconductor device in accordance with one or more embodiments described herein.

FIG. 14A illustrates an alternative seventh stage of production of a semiconductor device in accordance with one or more embodiments described herein.

FIG. 14B illustrates an alternative eight stage of production of a semiconductor device in accordance with one or more embodiments described herein.

FIG. 15 illustrates an alternative ninth stage of production of a semiconductor device in accordance with one or more embodiments described herein.

FIG. 16 illustrates a flow diagram of an example, non-limiting method of fabrication, by a fabrication system, of a semiconductor device in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, where like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

In traditional semiconductor device production, a continuous dielectric cap is deposited across an entire level of wiring. This can create issues during skip via production. Skip vias, also known as super vias, are vias that bypass intermediate layers of wiring within semiconductors. Accordingly, to pattern skip via channels, the continuous dielectric cap covering intermediate layers is etched through, often leading to damage to the intermediate level of wiring due to the etch chemicals and processes used to break through the dielectric cap.

In view of these issues, the described subject matter illustrates semiconductor devices comprising a discontinuous dielectric cap over an intermediate level of interconnect wiring, and a skip via aligned between portions of the discontinuous dielectric cap. As the cap is discontinuous (e.g., with gaps), skip vias can be patterned in these gaps without having to etch through the dielectric cap, thus easing production and reducing the chances of damaging the intermediate layer of wiring.

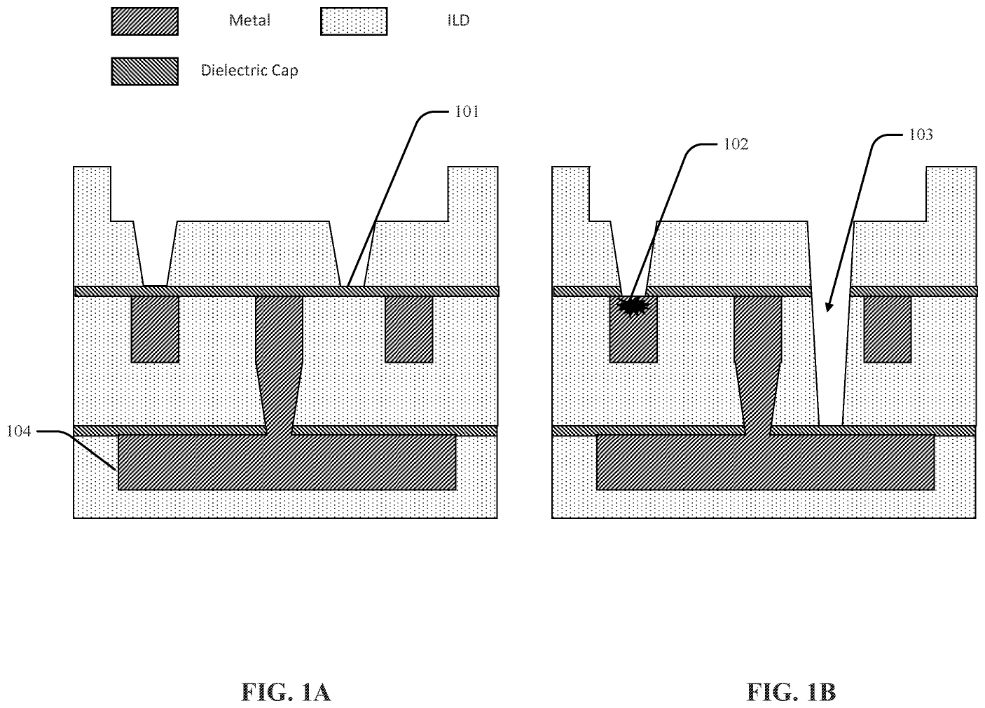

FIGS. 1A and 1B illustrate semiconductor devices with continuous dielectric caps in accordance with one or more embodiments described herein. As shown in FIG. 1A, dielectric cap 101 is continuous (e.g., running the entire length of the semiconductor device). Accordingly, patterning a skip via to layer 104 calls for etching through the continuous dielectric cap 101. As shown in FIG. 1B, the etching process used to break through dielectric cap 101 can also break through the dielectric cap over metal track 102, as they are at the same level. This exposes metal track 102 to damage or corrosion during the additional etching used to form skip via channel 103, thus negatively impacting performance of the finished device.

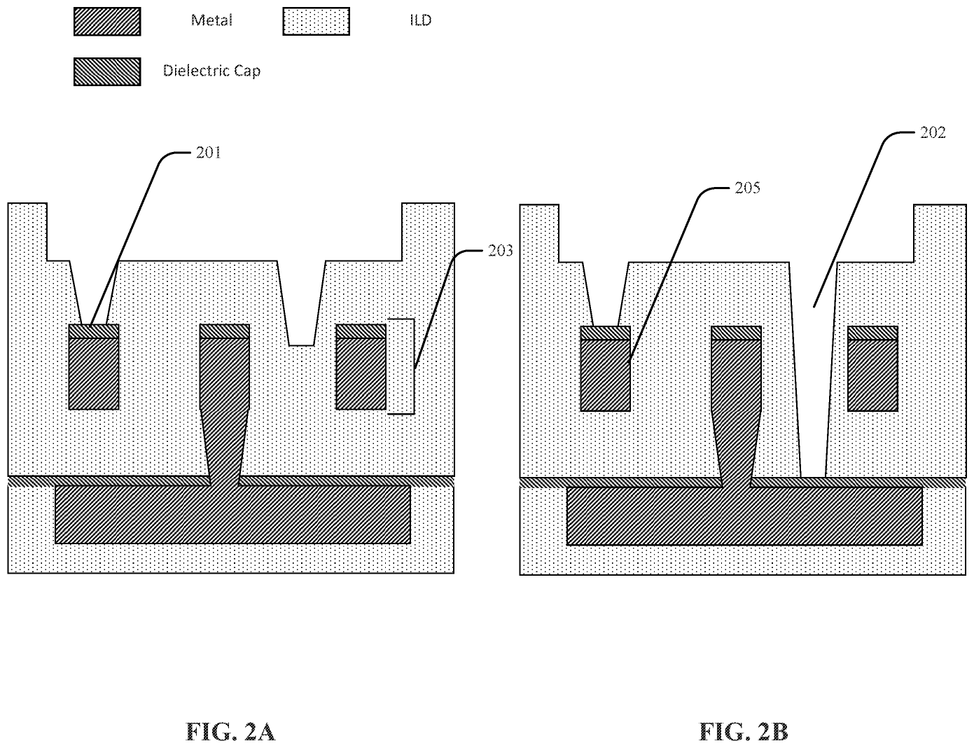

FIGS. 2A and 2B illustrate semiconductor devices with discontinuous dielectric caps in accordance with one or more embodiments described herein. As shown in FIG. 2A, dielectric cap 201 is discontinuous (e.g., only exists over metal tracks within second layer of wiring 203). As shown, in FIG. 2B, patterning skip via channel 202 does not call for breaking through dielectric cap 201, and thus metal track 205 is protected from the etching process by dielectric cap 201.

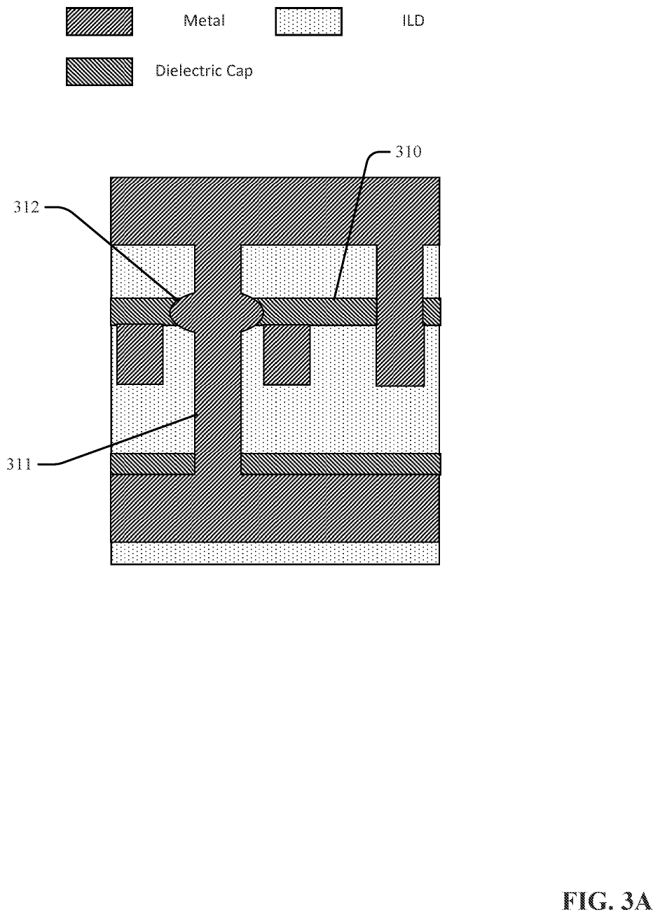

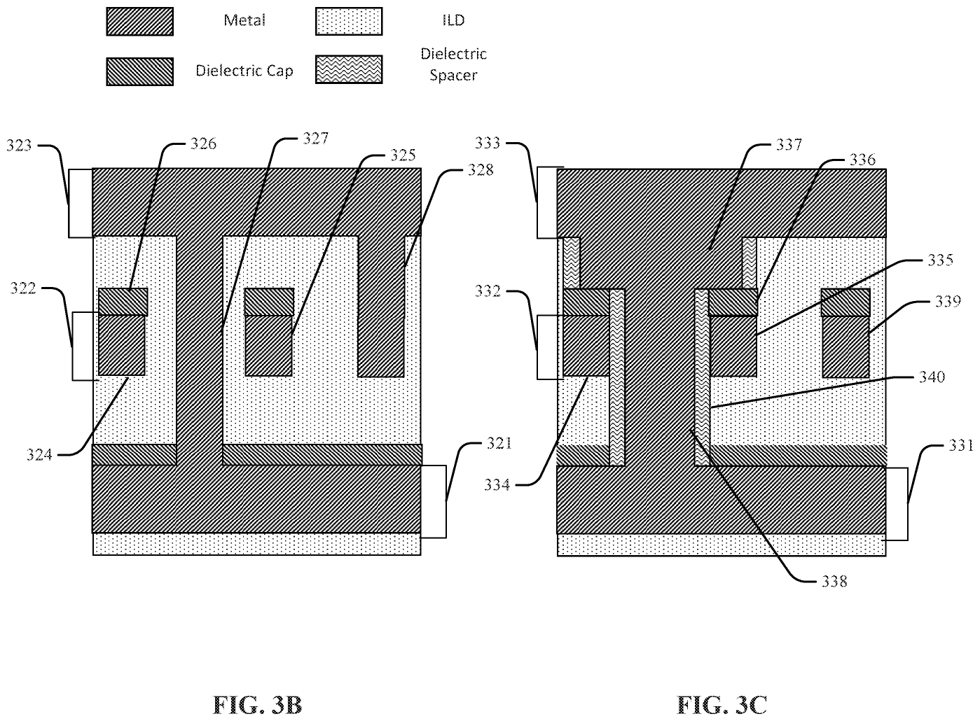

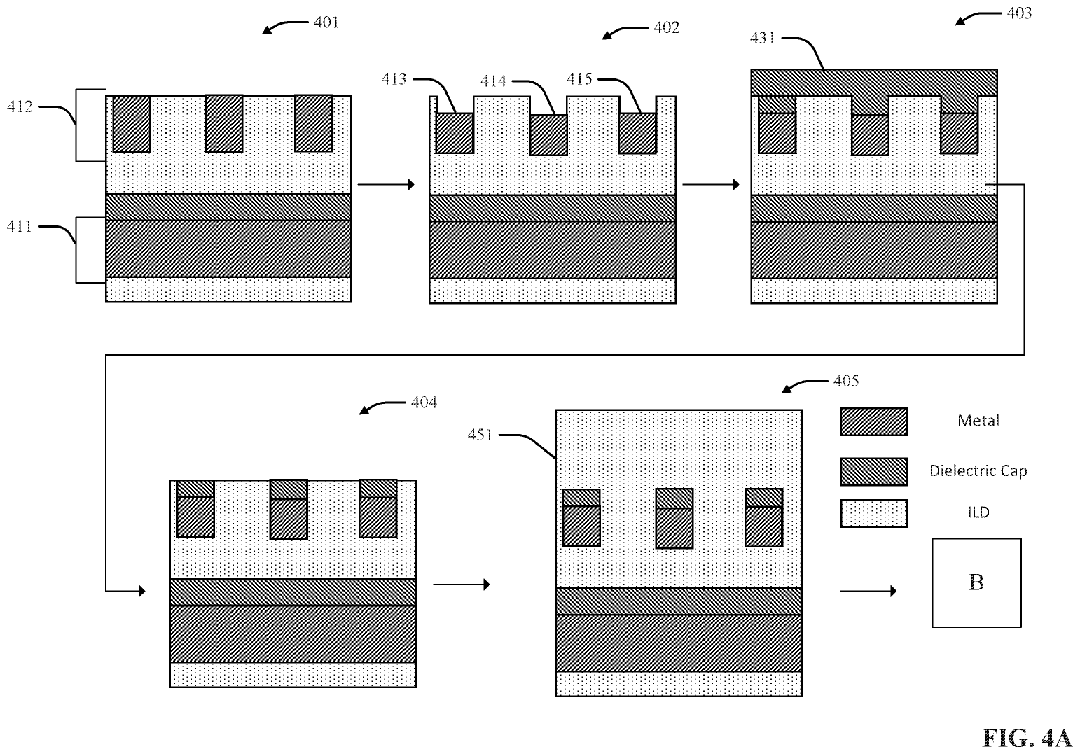

FIG. 3A illustrates a semiconductor device with a continuous dielectric cap in accordance with one or more embodiments described herein. As shown, dielectric cap 310 runs the width of the semiconductor device. Accordingly, patterning skip via 311 calls for punching thorough the continuous dielectric cap. Due to the etch chemistry of the dielectric cap 310, the skip via patterning process can etch away a portion of the sides of the dielectric cap 310, creating an unintended bulbous section 312, which can negatively impact performance of the semiconductor device.

FIG. 3B illustrates a semiconductor device in accordance with one or more embodiments described herein. As shown, FIG. 3B comprises a first level of interconnect wiring 321, a second level of interconnect wiring 322, and a third level of interconnect wiring 323. The second level of interconnect wiring 322 can comprise a first metal track 324 and a second metal track 325. FIG. 3B further comprises a discontinuous dielectric cap 326, that is present only over the first metal track 324 and the second metal track 325. As shown, skip via 327 is aligned between the first metal track 324 and the second metal track 325 and can connect the third level of interconnect wiring 323 to the first level of interconnect wiring 321. As dielectric cap 326 is discontinuous, the patterning for skip via 327 will not call for breaking through the dielectric cap 326, protecting the first metal track 324 and the second metal track 325. Furthermore, as described in greater detail below, via 328 and skip via 327 can be etched using a single mask, as opposed to using two individual masks, decreasing fabrication time and cost.

FIG. 3C illustrates a semiconductor device in accordance with one or more embodiments described herein. As shown, FIG. 3C comprises a first level of interconnect wiring 331, a second level of interconnect wiring 332, and a third level of interconnect wiring 333. The second level of interconnect wiring 332 can comprise a first metal track 334 and a second metal track 335. FIG. 3C further comprises a discontinuous dielectric cap 336, that is present only over the first metal track 334 and the second metal track 335. FIG. 3C additionally comprises a skip via comprising an upper section 337 and a lower section 338. In some embodiments upper section 337 can comprise a greater width relative to a width of the lower section 338. The lower section 338 can be aligned between the first metal track 334 and the second metal track 335. Additionally, sidewalls of the upper section 337 and the lower section 338 can comprise a dielectric spacer material 340. As described in greater detail below, in some embodiments the upper section can extend over a third metal track 339 and the semiconductor device can comprise a second skip via lower section aligned between the second metal track 335 and the third metal track 339.

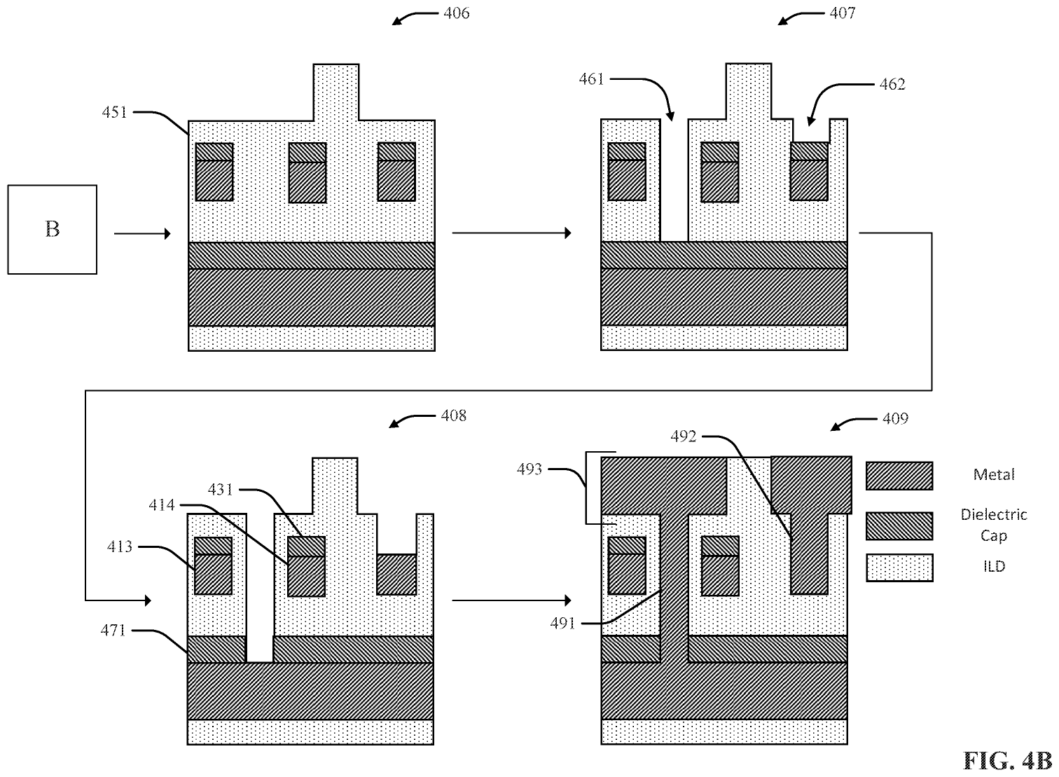

FIG. 4A illustrates a first portion of a production process for fabrication of a semiconductor device in accordance with one or more embodiments described herein. Stage 401 illustrates a first stage of fabrication of a semiconductor device in accordance with one or more embodiments described herein. As shown at stage 401, the device can comprise a first level of interconnect wiring 411 and a second level of interconnect wiring 412. The second level of interconnect wiring can comprise one or more metal tracks, such as first metal track 413, second metal track 414 and third metal track 415.

At stage 402, the one or more metal tracks of the second level of interconnect wiring 412 (e.g., first metal track 413, second metal track 414 and third metal track 415) can be recessed. At stage 403, a dielectric cap 431 can be deposited on top of the device, filling the recessions above the one or more metal tracks. At stage 404, the dielectric cap 431 can be removed from the areas between the one or more metal tracks through a process such as chemical-mechanical-polishing (CMP). At stage 405, additional intermediate level dielectric (ILD) 451 can be deposited on top of the device.

FIG. 4B illustrates a second portion of a production process for fabrication of a semiconductor device in accordance with one or more embodiments described herein. At stage 406, a lithographic etching and patterning process can be utilized to recess ILD 451 to prepare for fabrication of a third level of interconnect wiring. At 407, skip via channel 461 and via channel 462 can be etched using the same mask, as opposed to using multiple etching masks in other design processes. At 408, the dielectric cap 431 and the second dielectric cap 471 can be removed. As the dielectric cap 431 is not exposed over the first metal track 413 and the second metal track 414, there is no risk of damage to the first metal track 413 and the second metal track 414 as compared to other fabrication methods. At 409, a metallization process can be utilized to form skip via 491, via 492 and third level of interconnect wiring 493.

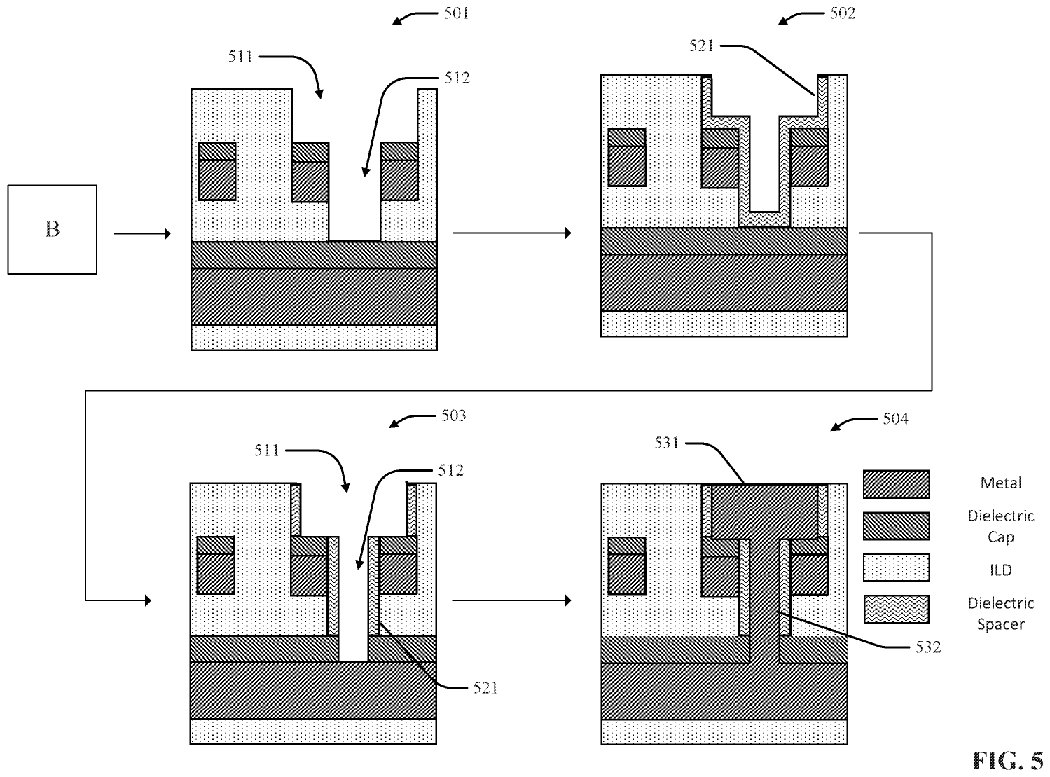

FIG. 5 illustrates an alternative second portion of a production process for fabrication of a semiconductor device in accordance with one or more embodiments described herein. At stage 501, an etching process can be utilized to pattern an upper skip via channel 511, and a lower skip via channel 512, wherein the upper skip via channel 511 comprises a width greater than the lower skip via channel 512. At stage 502, a dielectric barrier or spacer material 521 can be deposited into the upper skip via channel 511 and the lower skip via channel 512. At 503, a directional etching process can be utilized to remove the dielectric spacer material 521 from the bottom of the upper skip via channel 511 and the bottom of the lower skip via channel 512. An etch stop layer removal processes can then be utilized to expose the first level of interconnect wiring 411. At stage 504, a metallization process can be utilized to fill in the upper skip via channel 511 and the lower skip via channel 512 to form a skip via. As shown, the skip via comprises an upper section 531 and a lower section 532, wherein the upper section 531 comprises a width greater than the lower section 532.

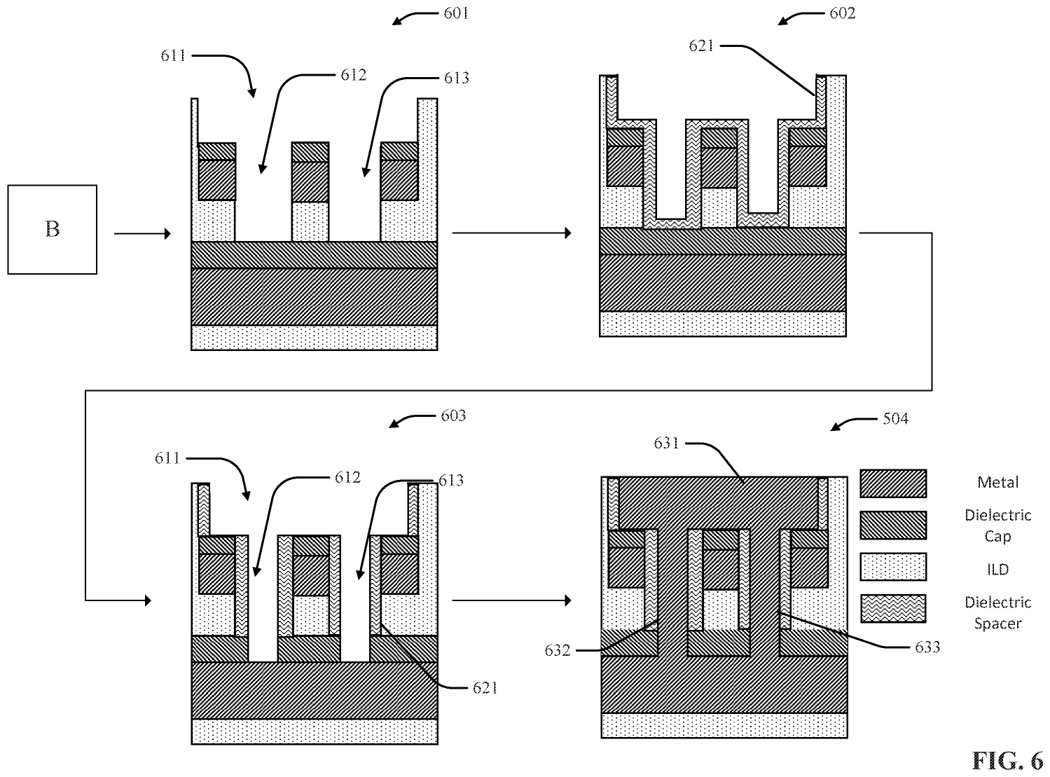

FIG. 6 illustrates an alternative second portion of a production process for fabrication of a semiconductor device in accordance with one or more embodiments described herein. At stage 601, an etching process can be utilized to pattern an upper skip via channel 611, and a first lower skip via channel 612 and a second lower skip via channel 613, wherein the upper skip via channel 611 comprises a width greater than the width of the first lower skip via channel 612 or the width of the second lower skip via channel 613. At stage 602, a dielectric barrier or spacer material 621 can be deposited into the upper skip via channel 611, the first lower skip via channel 612 and the second lower skip via channel 613. At 603, a directional etching process can be utilized to remove the dielectric spacer material 621 from the bottom of the upper skip via channel 611, the bottom of the first lower skip via channel 612 and the bottom of the second lower skip via channel 613. An etch stop layer removal processes can then be utilized to expose the first level of interconnect wiring 411. At stage 604, a metallization process can be utilized to fill in the upper skip via channel 611, the first lower skip via channel 612 and the second lower skip via channel 613 to form a skip via. As shown, the skip via comprises an upper section 631, a first lower section 632 and a second lower section 633, wherein the upper section 631 comprises a width greater than the width of first lower section 632 or the width of the second lower section 633.

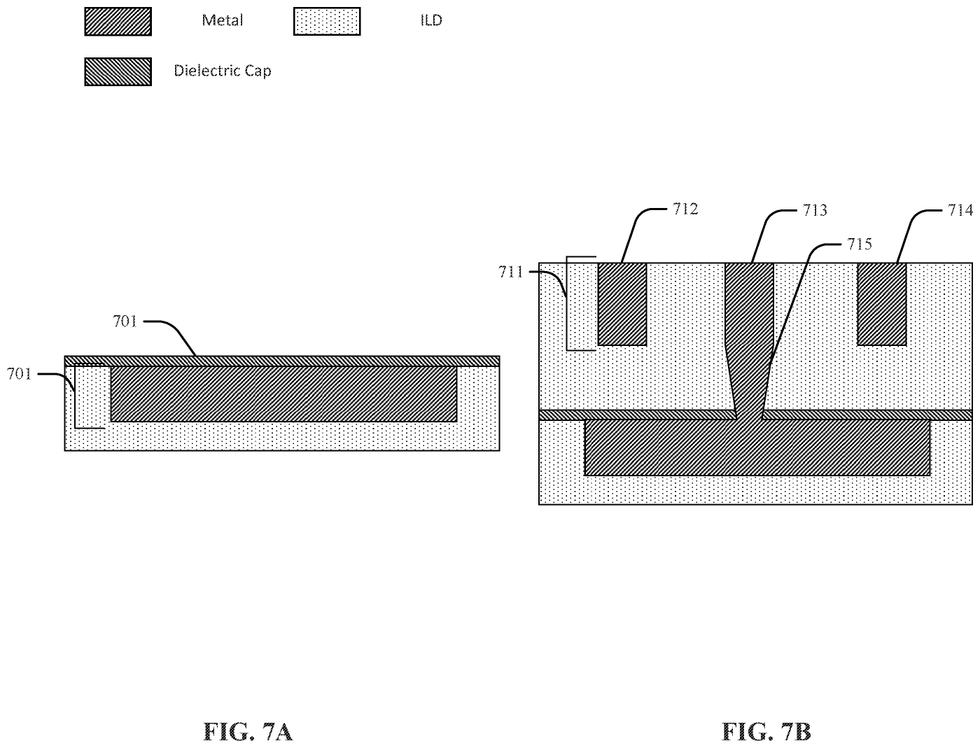

FIG. 7A illustrates a first stage of production of a semiconductor device in accordance with one or more embodiments described herein. As shown, FIG. 7A comprises a first layer of interconnect wiring 701 and a dielectric cap 702. In an embodiment, dielectric cap 702 can comprise a material such as SiCN.

FIG. 7B illustrates a second stage of production of a semiconductor device in accordance with one or more embodiments described herein. As shown, a second level of interconnect wiring 711 comprising one or more metal tracks (e.g., track 712, track 713 and track 714) and a via 715 connecting the first level of interconnect wiring 701 to the second level of interconnect wiring 711 can be formed by a metallization process.

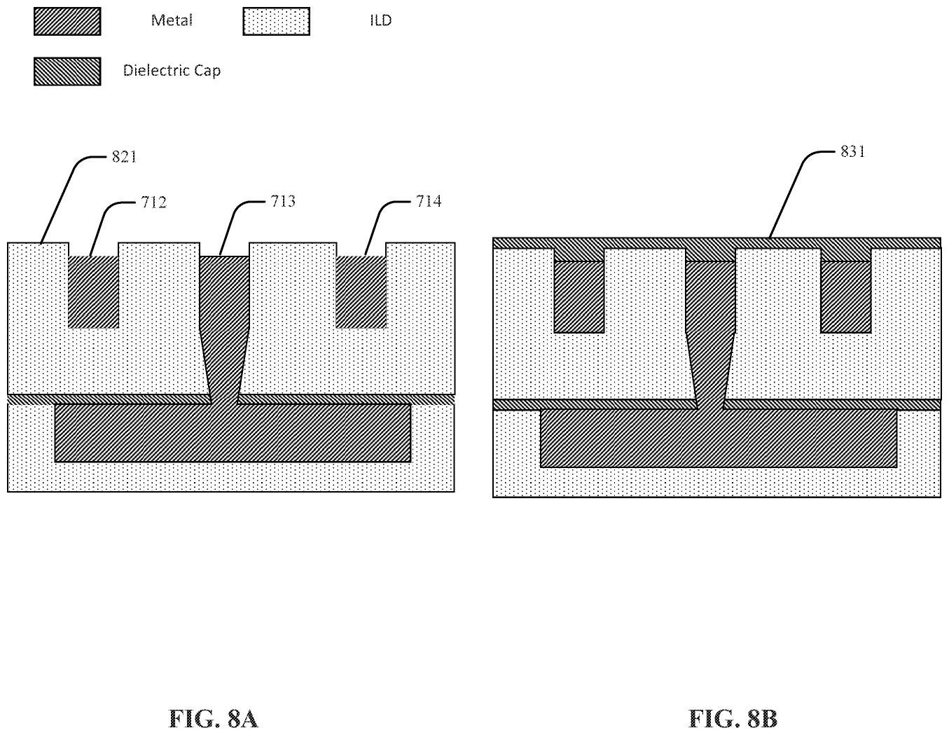

FIG. 8A illustrates a third stage of production of a semiconductor device in accordance with one or more embodiments described herein. As shown, the one or more metal tracks (e.g., track 712, track 713 and track 714) can be recessed below the level of the surrounding ILD 821. Alternatively, selective IDL growth can be utilized to grow the ILD 821 surrounding the one or metal tracks.

FIG. 8B illustrates a fourth stage of production of a semiconductor device in accordance with one or more embodiments described herein. As shown, a dielectric cap 831 can be deposited on top of ILD 821. In an embodiment, dielectric cap 831 can comprise a material such as SiCN.

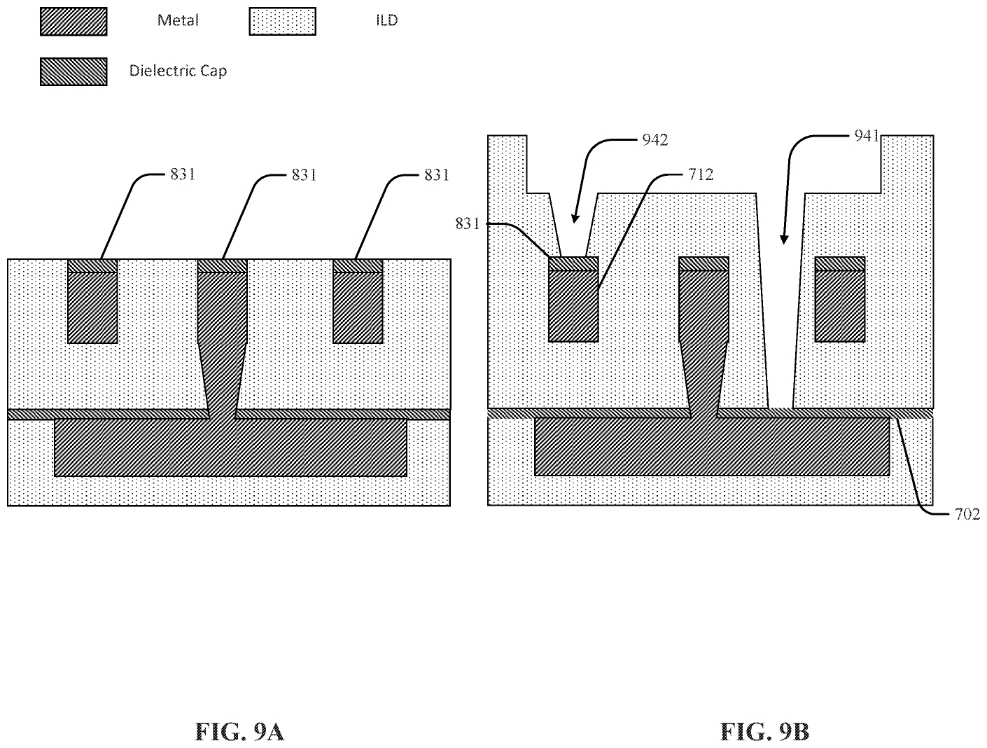

FIG. 9A illustrates a fifth stage of production of a semiconductor device in accordance with one or more embodiments described herein. As shown, a CMP process can be utilized to remove the dielectric cap 831 in the regions between the one or more metal tracks. Accordingly, the dielectric cap 831 is now discontinuous, as it only exists on top of track 712, track 713 and track 714.

FIG. 9B illustrates a sixth stage of production of a semiconductor device in accordance with one or more embodiments described herein. As shown, a skip via channel 941 and a via channel 942 can be patterned. Dielectric cap 702 and dielectric cap 831 can be utilized as etch stop layers to prevent the channel patterning process from damaging track 712 or the first level of interconnect wiring. Furthermore, this allows for skip via channel 941 and via channel 942 to be patterned utilizing a single mask, as opposed to separate masks.

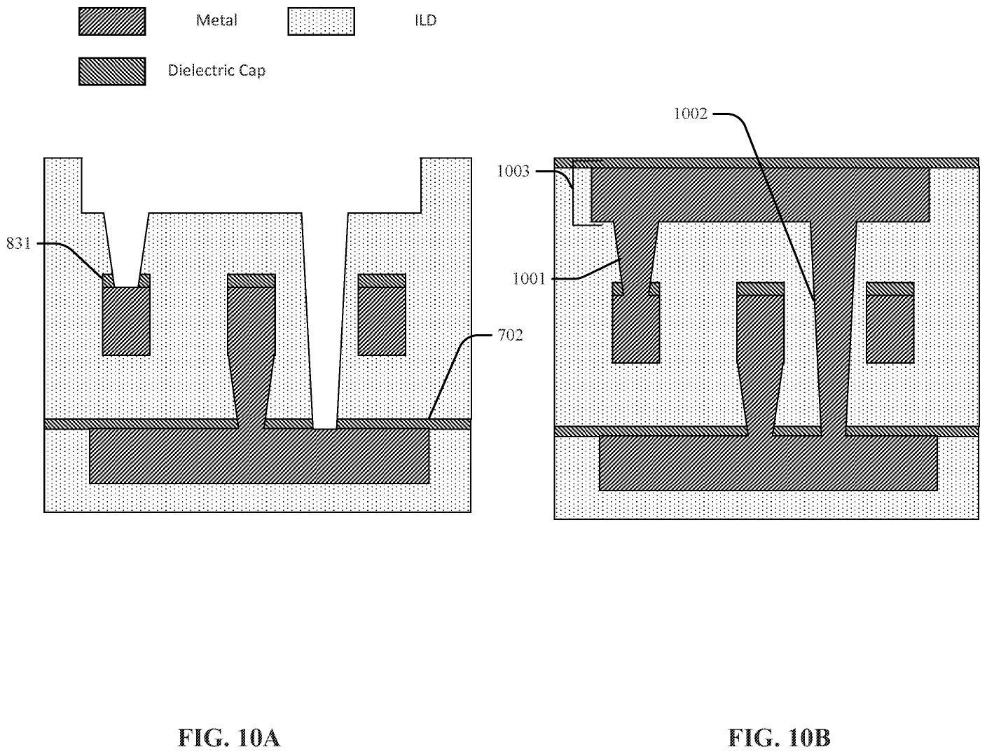

FIG. 10A illustrates a seventh stage of production of a semiconductor device in accordance with one or more embodiments described herein. As shown, dielectric cap 702 and dielectric cap 831 can be opened to expose track 712 and first level of interconnect wiring 701.

FIG. 10B illustrates an eighth stage of production of a semiconductor device in accordance with one or more embodiments described herein. As shown, a metallization process can be utilized to form via 1001 in via channel 942, skip via 1002 in skip via channel 941 and third level of interconnect wiring 1003.

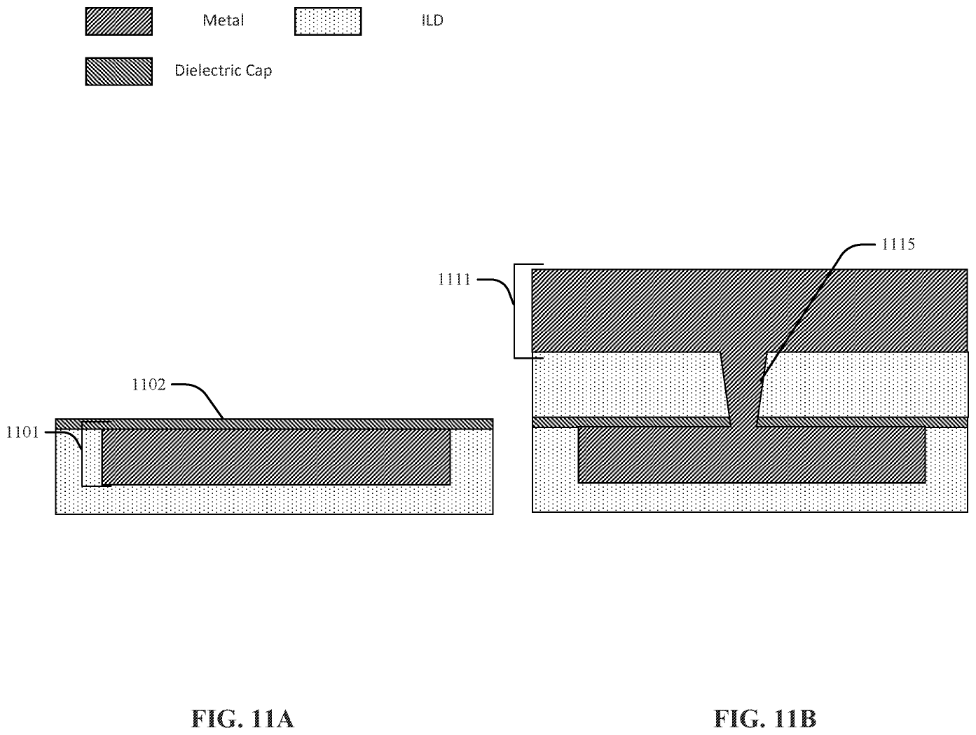

FIG. 11A illustrates an alternative first stage of production of a semiconductor device in accordance with one or more embodiments described herein. As shown, FIG. 11A comprises a first layer of interconnect wiring 1101 and a dielectric cap 1102. In an embodiment, dielectric cap 1102 can comprise a material such as SiCN.

FIG. 11B illustrates an alternative second stage of production of a semiconductor device in accordance with one or more embodiments described herein. As shown, a second level of interconnect wiring 1111 and a via 1115 connecting the first level of interconnect wiring 1101 to the second level of interconnect wiring 1111 can be formed by a metallization process.

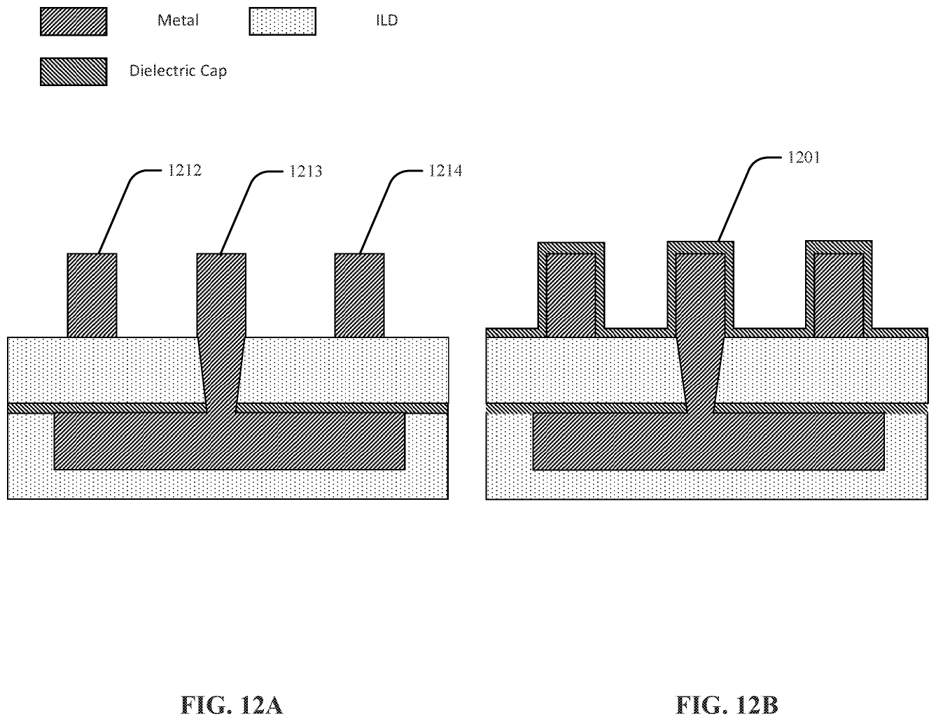

FIG. 12A illustrates an alternative third stage of production of a semiconductor device in accordance with one or more embodiments described herein. As shown, a subtractive metal etching process can be utilized to form one or more metal tracks (e.g., track 1212, track 1213 and track 1214).

FIG. 12B illustrates an alternative fourth stage of production of a semiconductor device in accordance with one or more embodiments described herein. As shown, a conformal cap deposition process can be utilized to deposit dielectric cap 1201 onto the second level of interconnect wiring 1111.

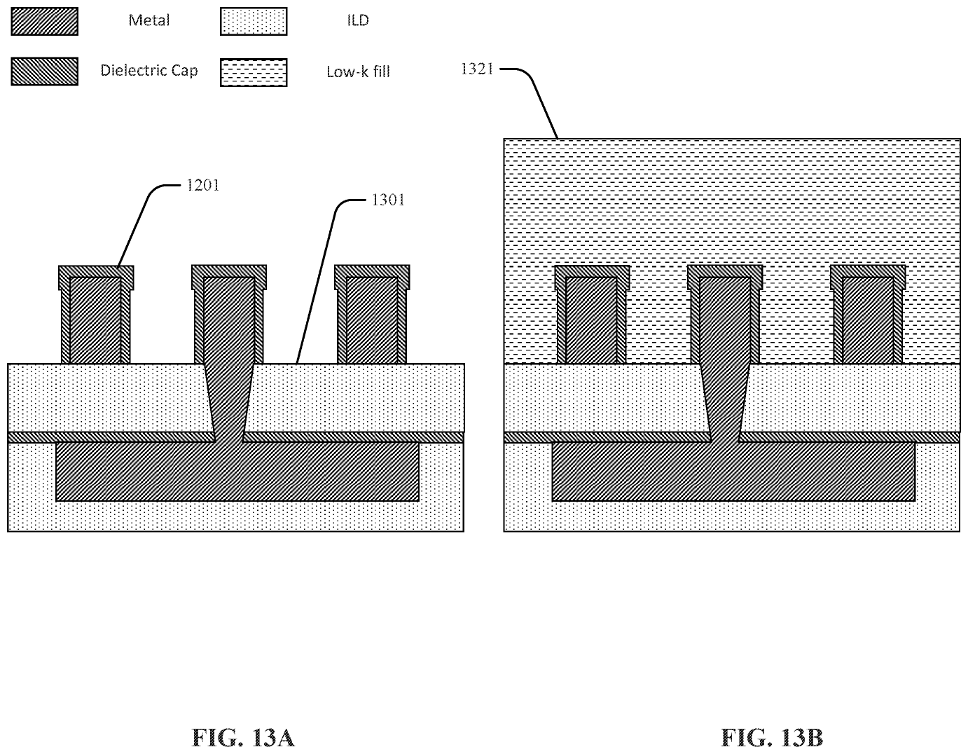

FIG. 13A illustrates an alternative fifth stage of production of a semiconductor device in accordance with one or more embodiments described herein. As shown, a non-conformal cap deposition process can be utilized to increase the thickness of the dielectric cap 1201 above track 1212, track 1213 and track 1214. Additionally, a cap etch back process can be utilized to remove the dielectric cap 1201 from on top of ILD layer 1301.

FIG. 13B illustrates an alternative sixth stage of production of a semiconductor device in accordance with one or more embodiments described herein. As shown, a low-k fill material 1321 can be deposited on top of the device using a process such as furnace chemical vapor deposition (fCVD).

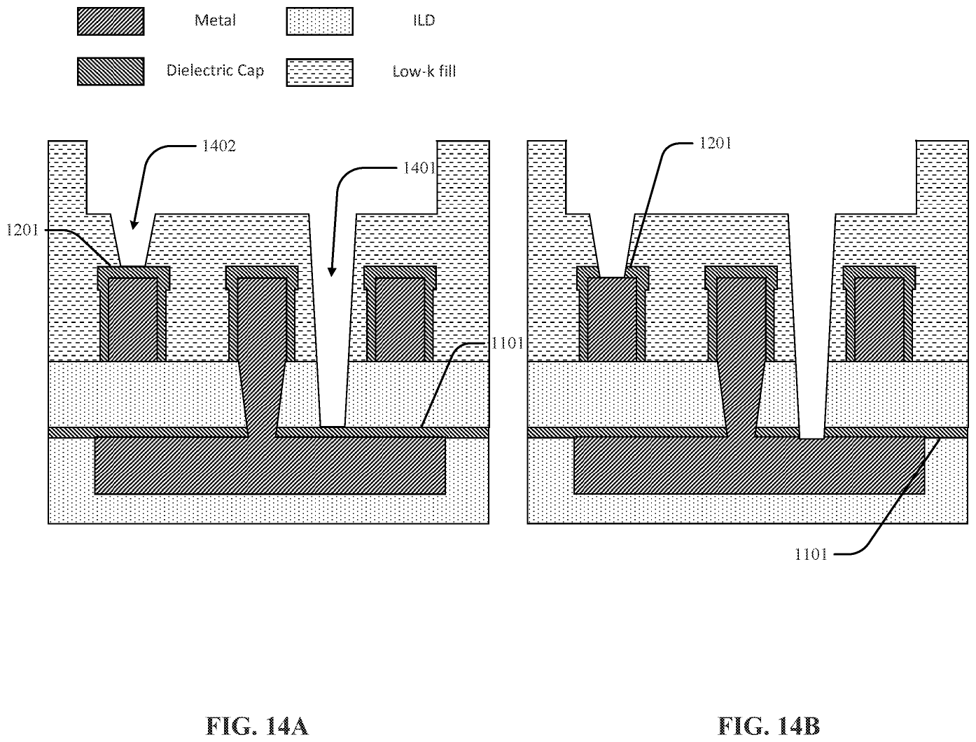

FIG. 14A illustrates an alternative seventh stage of production of a semiconductor device in accordance with one or more embodiments described herein. As shown, a skip via channel 1401 and a via channel 1402 can be patterned utilizing dielectric cap 1102 and dielectric cap 1201 as etch stop layers.

FIG. 14B illustrates an alternative eighth stage of production of a semiconductor device in accordance with one or more embodiments described herein. As shown, dielectric cap 1102 and dielectric cap 1201 can be opened to expose track 1212 and first level of interconnect wiring 1101.

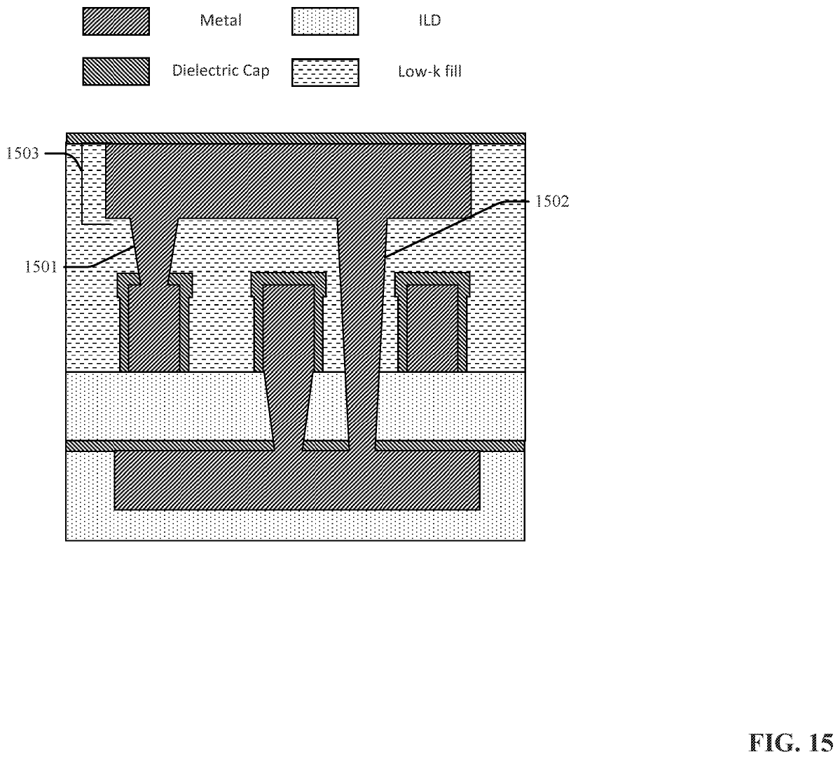

FIG. 15 illustrates an alternative ninth stage of production of a semiconductor device in accordance with one or more embodiments described herein. As shown, a metallization process can be utilized to form via 1501 in via channel 1402, skip via 1502 in skip via channel 1401 and third level of interconnect wiring 1503.

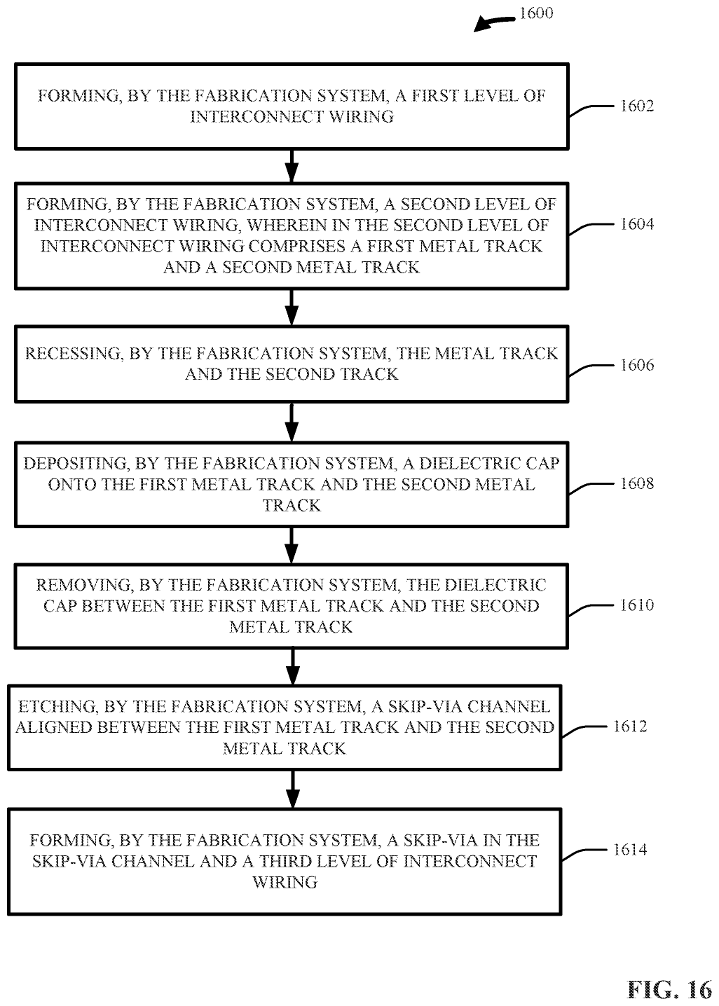

FIG. 16 illustrates a flow diagram of an example, non-limiting method of fabrication 1600, by a fabrication system, of a semiconductor device in accordance with one or more embodiments described herein.

At 1602, method 1600 can comprise forming, by the fabrication system, a first level of interconnect wiring.

At 1604, method 1600 can comprise forming, by the fabrication system, a second level of interconnect wiring, wherein the second level of interconnect wiring comprises a first metal track and a second metal track.

At 1606, method 1600 can comprise recessing, by the fabrication system, the first metal track and the second metal track.

At 1608, method 1600 can comprise depositing, by the fabrication system, a dielectric cap onto the first metal track and the second metal track.

At 1610, method 1600 can comprise removing, by the fabrication system, the dielectric cap between the first metal track and the second metal track. In some embodiments, portions of the dielectric cap can be removed utilizing a CMP process.

At 1612, method 1600 can comprise etching, by the fabrication system, a skip via channel aligned between the first metal track and the second metal track.

At 1614, method 1600 can comprise forming, by the fabrication system, a skip via in the skip via channel and a third level of interconnect wiring.

An advantage of such methods, devices and/or systems described herein is that they enable production of semiconductor devices with a decreased chance of defects. For example, by utilizing a discontinuous dielectric cap, skip vias can be patterned without punching through a dielectric cap over an intermediate level of interconnect wiring, thus protecting the intermediate layer of wiring from potential damage during fabrication. A practical application of the above-described devices is that they over decreased chance of production defect, and thus improved performance, when compared to other designs.

What is claimed is:

1. A semiconductor device comprising:
a first level of interconnect wiring;
a second level of interconnect wiring;
a third level of interconnect wiring;
a discontinuous dielectric cap over the second level of interconnect wiring; and
a skip via connecting the first level of interconnect wiring to the third level of interconnect wiring.

2. The semiconductor device of claim 1, further comprising a first via connecting the second level of interconnect wiring to the third level of interconnect wiring; and
a second via connecting the first level of interconnect wiring to the second level of interconnect wiring.

3. The semiconductor device of claim 1, wherein the second level of interconnect wiring comprises a first metal track and a second metal track.

4. The semiconductor device of claim 3, wherein the skip via is aligned between the first metal track and the second metal track.

5. The semiconductor device of claim 1, wherein sidewalls of the skip via comprise a dielectric barrier material.

6. A semiconductor device comprising:
a first level of interconnect wiring;
a second level of interconnect wiring;
a third level of interconnect wiring;
a discontinuous dielectric cap over the second level of interconnect wiring; and
a skip via connecting the first level of interconnect wiring to the third level of interconnect wiring, wherein the skip via comprises an upper section and a lower section, and wherein the upper section comprises a width greater than a width of the lower section.

7. The semiconductor device of claim 6, wherein the upper section connects to the third level of interconnect wiring and the lower section connects to the first level of interconnect wiring.

8. The semiconductor device of claim 6, wherein the second level of interconnect wiring comprises a first metal track and a second metal track.

9. The semiconductor device of claim 8, wherein the lower section is aligned between the first metal track and the second metal track, and wherein the upper section extends over the first metal track and the second metal track.

10. The semiconductor device of claim 6, wherein sidewalls of the upper section and the sidewalls of the lower section comprise a dielectric barrier material.

11. The semiconductor device of claim 8, wherein the skip via comprises a second lower section, wherein the second lower section connects to the upper section.

12. The semiconductor device of claim 11, wherein the second level of interconnect wiring comprises a third metal track.

13. The semiconductor device of claim 12, wherein the second lower section is aligned between the second metal track and the third metal track, and wherein the upper section extends over the third metal track.

14. A method for fabricating a semiconductor device by a fabrication system, the method comprising:
forming, by the fabrication system, a first level of interconnect wiring;
forming, by the fabrication system, a second level of interconnect wiring, wherein in the second level of interconnect wiring comprises a first metal track and a second metal track;
recessing, by the fabrication system, the first metal track and the second metal track;
depositing, by the fabrication system, a dielectric cap onto the first metal track and the second metal track;
removing, by the fabrication system, the dielectric cap between the first metal track and the second metal track;
etching, by the fabrication system, a skip via channel aligned between the first metal track and the second metal track;
forming, by the fabrication system, a skip via in the skip via channel and a third level of interconnect wiring.

15. The method of claim 14, wherein the etching the skip via channel further comprise
etching, by the fabrication system, a via channel; and
wherein the forming the skip via further comprises forming, by the fabrication system, a via in the via channel.

16. The method of claim 14, wherein the etching the skip via channel comprises etching an upper section and a lower section and wherein the lower section is aligned between the first metal track and the second metal track.

17. The method of claim 16, wherein the upper section comprises a width greater than the lower section.

18. The method of claim 14, further comprising depositing, by the fabrication system, a dielectric fill material on sidewalls of the skip via channel.

19. The method of claim 16, wherein the second level of interconnect wiring comprises a third metal track.

20. The method of claim 19, further comprising etching, by the fabrication system, a second lower section, wherein the second lower section is aligned between the second metal track and the third metal track.
